(19) United States
(12) Patent Application Publication
(10) Pub. No.: US 2009/0028204 A1
(43) Pub. Date: Jan. 29, 2009

(54) SEMICONDUCTOR LASER DEVICE

(75) Inventors: Ryoji Hiroyama, Kyo-tanabe-shi (JP); Yasuhiko Nomura, Osaka-shi (JP); Masayuki Hata, Kadoma-shi (JP); Yasuto Miyake, Hirakata-shi (JP)

Correspondence Address: DITTHAVONG MORI & STEINER, P.C., 918 Prince St., Alexandria, VA, 22314, US

(73) Assignee: Sanyo Electric Co., Ltd., Moriguchi-shi (JP)

(21) Appl. No.: 12/179,254

(22) Filed: Jul. 24, 2008

(30) Foreign Application Priority Data
Jul. 24, 2007 (JP) 2007-191812

(51) Int. Cl. H01S 5/026

(52) U.S. Cl. 372/50.1

(57) ABSTRACT

A semiconductor laser device includes a substrate made of a nitride-based semiconductor and a waveguide formed on a principal surface of the substrate, wherein the substrate includes a dislocation concentrated region arranged so as to obliquely extend with respect to the principal surface of the substrate, and the waveguide is so formed as to be located above the dislocation concentrated region and also located on a region except a portion where the dislocation concentrated region is present in the principal surface of the substrate.

### CROSS-REFERENCE TO RELATED APPLICATIONS

The priority application number JP2007-191812, Semiconductor Laser Device, Jul. 24, 2007, Ryoji Hiroyama et al, upon which this patent application is based is hereby incorporated by reference.

### BACKGROUND OF THE INVENTION

1. Field of the Invention

The present invention relates to a semiconductor laser device, and more particularly, it relates to a semiconductor laser device comprising a substrate made of a nitride-based semiconductor.

2. Description of the Background Art

A semiconductor laser device comprising a substrate made of nitride is known in general, as disclosed in Japanese Patent Laying-Open Nos. 2003-133649 and 2002-29897, for example.

The aforementioned Japanese Patent Laying-Open No. 2003-133649 discloses a semiconductor laser device provided with a semiconductor layer including a waveguide on a substrate including a dislocation concentrated region extending in a direction perpendicular to a principal surface. This dislocation concentrated region is known as a region having a resistance higher than that of other potion.

The aforementioned Japanese Patent Laying-Open No. 2002-29897 discloses a substrate including linear threading dislocations extending in a direction parallel to a principal surface.

In the semiconductor laser device, it is known that light disadvantageously leaks from the waveguide of the semiconductor layer to a side of the substrate.

In the conventional semiconductor laser device disclosed in Japanese Patent Laying-Open No. 2003-133649, a strong peak (substrate mode) is disadvantageously present on the side of the substrate of a vertical transverse mode, when the light disadvantageously leaks from the waveguide of the semiconductor layer to the side of the substrate.

### SUMMARY OF THE INVENTION

A semiconductor laser device according to an aspect of the present invention comprises a substrate made of a nitride-based semiconductor and a waveguide formed on a principal surface of the substrate, wherein the substrate includes a dislocation concentrated region arranged so as to obliquely extend with respect to the principal surface of the substrate, and the waveguide is so formed as to be located above the dislocation concentrated region and also located on a region except a portion where the dislocation concentrated region is present in the principal surface of the substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a structure of a semiconductor laser device according to a first embodiment of the present invention, as viewed from a [1-100] direction;

FIG. 2 is a sectional view for illustrating a fabricating process for a substrate of the semiconductor laser device according to the first embodiment, as viewed from a [1-100] direction;

FIGS. 3 to 6 are sectional views for illustrating a fabricating process for the semiconductor laser device according to the first embodiment, as viewed from a [1-100] direction;

FIG. 7 is a sectional view showing a structure of a semiconductor laser device according to a comparative example;

FIG. 8 is a diagram showing a vertical transverse mode of the semiconductor laser device according to the comparative example;

FIG. 9 is a diagram showing a vertical transverse mode of the semiconductor laser device according to the first embodiment;

FIG. 10 is a sectional view showing a structure of a modification of a semiconductor laser device according to the first embodiment, as viewed from the [1-100] direction;

FIG. 11 is a sectional view showing a structure of a semiconductor laser device according to a second embodiment of the present invention, as viewed from a [0001] direction;

FIG. 12 is a plan view for illustrating a fabricating process for a substrate of the semiconductor laser device according to the second embodiment, as viewed from the [0001] direction;

FIGS. 13 to 16 are a sectional view for illustrating a fabricating process for the semiconductor laser device according to the second embodiment, as viewed from the [0001] direction;

FIG. 17 is a sectional view showing a structure of a modification of a semiconductor laser device according to the second embodiment, as viewed from the [0001] direction; and

FIG. 18 is a plan view for illustrating a fabricating process for a substrate of a modification of the semiconductor laser device according to the second embodiment, as viewed from the [0001] direction.

### DESCRIPTION OF THE PREFERRED EMBODIMENTS

Embodiments of the present invention will be hereinafter described with reference to the drawings.

### First Embodiment

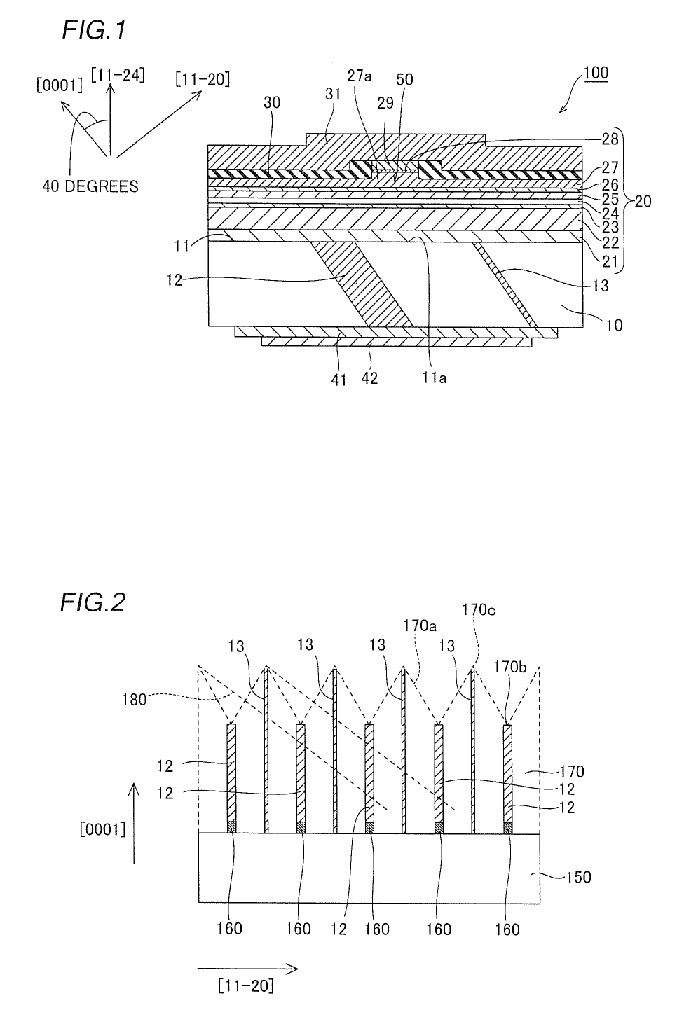

A structure of a semiconductor laser device 100 according to a first embodiment will be now described with reference to FIG. 1.

As shown in FIG. 1, the semiconductor laser device 100 according to the first embodiment is a laser device emitting a blue-violet laser of 405 nm and comprises a substrate 10, a semiconductor layer 20, a p-side ohmic electrode 29, current blocking layers 30, a p-side pad electrode 31, an n-side ohmic electrode 41 and an n-side pad electrode 42.

The substrate 10 is made of n-type GaN and has a thickness of about 100 μm. According to the first embodiment, a principal surface 11 of the substrate 10 is substantially equal to a (11-24) plane. In the substrate 10, a planar dislocation concentrated region 12 and a high resistance region 13 are so arranged as to extend parallel to a (11-20) plane. The dislocation concentrated region 12 and the high resistance region 13 are inclined by about 50 degrees with respect to the principal surface 11 of the substrate 10. The dislocation concentrated region 12 has a function of absorbing light. The dislocation concentrated region 12 has a crystal structure with a large number of crystal defects and discontinuous with crystal portions therearound, and hence has a high resistance value. The high resistance region 13 includes a small amount of impurities as compared with portions therearound, and hence has a high resistance value. This substrate 10 is so formed that a current can flow along a current path (region between the dislocation concentrated region 12 and the high resistance region 13) formed by a low resistance region with a resistance value lower than those of the dislocation concentrated region 12 and the high resistance region 13, while avoiding the dislocation concentrated region 12 and the high resistance region 13 with high resistances.

According to the first embodiment, the dislocation concentrated region 12 is so arranged in the substrate 10 as to obliquely extend from the principal surface 11 of the substrate 10 to reach a region below a ridge portion 50 described later and extend up to a lower surface of the substrate 10. Therefore, the substrate 10 has a region completely blocked from the principal surface 11 to the lower surface of the substrate 10 along a thickness direction of the substrate 10 by the dislocation concentrated region 12. The high resistance region 13 is also so arranged as to extend from the principal surface 11 of the substrate 10 toward the lower surface of the substrate 10 through the inside of the substrate 10.

According to the first embodiment, the dislocation concentrated region 12 and the high resistance region 13 are so arranged as to extend substantially parallel to a [1-100] direction (perpendicular to the plane of FIG. 1) at a prescribed interval (about 156 μm) in the substrate 10. Thus, a sectional area of the current path is so formed as to be substantially constant along an extensional direction of the ridge portion 50 described later.

The semiconductor layer 20 includes a buffer layer 21 made of Al_{0.01}Ga_{0.99}N, having a thickness of about 1.0 μm, an n-side cladding layer 22 made of n-type Al_{0.07}Ga_{0.93}N doped with Ge, having a thickness of about 1.9 μm and formed on the buffer layer 21 and an n-side carrier blocking layer 23 made of Al_{0.2}Ga_{0.8}N having a thickness of about 20 nm and formed on the n-side cladding layer 22 and an emission layer 24 formed on the n-side carrier blocking layer 23.

The emission layer 24 has a multiple quantum well (MQW) structure. The emission layer 24 consists of an MQW active layer obtained by alternately stacking three quantum well layers made of InₓGa₁₋ₓN, each having a thickness of about 2.5 nm and three quantum barrier layers made of In_{y}Ga_{1-y}N, each having a thickness of about 20 nm. In this embodiment, x>y, and x=0.15 and y=0.02.

The semiconductor layer 20 further includes a p-side optical guide layer 25 made of In_{0.01}Ga_{0.99}N, having a thickness of about 80 nm and formed on the emission layer 24, a p-side carrier blocking layer 26 made of Al_{0.2}Ga_{0.8}N, having a thickness of about 20 nm and formed on the p-side optical guide layer 25, a p-side cladding layer 27 made of Al_{0.07}Ga_{0.93}N doped with Mg, having a thickness of about 0.45 μm and formed on the p-side carrier blocking layer 26 and a p-side contact layer 28 made of In_{0.07}Ga_{0.93}N, having a thickness of about 3 nm and formed on the p-side cladding layer 27. The p-side cladding layer 27 is provided with a projecting portion 27a having a thickness of about 0.4 μm. The p-side contact layer 28 is formed on the projecting portion 27a of the p-side cladding layer 27. The ridge portion 50 for forming a waveguide is formed by the projecting portion 27a of the p-side cladding layer 27 and the p-side contact layer 28. The ridge portion 50 is so formed as to extend in the [1-100] direction (perpendicular to the plane of FIG. 1).

According to the first embodiment, the ridge portion 50 is formed on a region 11a except portions where the dislocation concentrated region 12 and the high resistance region 13 are present in the principal surface 11 of the substrate 10. The ridge portion 50 is so formed as to have a width of about 1.5 μm and extend along the [1-100] direction (perpendicular to the plane of FIG. 1).

The p-side ohmic electrode 29 is formed on the p-side contact layer 28. The current blocking layers 30 made of SiO₂, having a thickness of about 0.2 μm is so formed as to cover an upper surface of the p-side cladding layer 27 and the side surfaces of the ridge portion 50 and the p-side ohmic electrode 29. The p-side pad electrode 31 is so formed as to cover upper surfaces of the p-side ohmic electrode 29 and the current blocking layers 30. The n-side ohmic electrode 41 and the n-side pad electrode 42 are successively formed on the lower surface of the substrate 10 from a side of the substrate 10. At this time, according to the first embodiment, an n-type ohmic electrode 41 is so formed as to entirely cover the dislocation concentrated region 12, the high resistance region 13 and a region between portions where the dislocation concentrated region 12 and the high resistance region 13 are present in the lower surface of the substrate 10. The n-type ohmic electrode 41 is an example of the “electrode layer” in the present invention.

A fabricating process for the semiconductor laser device 100 according to the first embodiment will be now described with reference to FIGS. 1 to 6.

As a fabricating process for the substrate 10, amorphous or polycrystalline seeds for generating the dislocation 160 are so formed on a GaAs substrate 150 having a (111) plane as a principal surface as to extend in the [1-100] direction (perpendicular to the plane of FIG. 1) at intervals of about 200 μm in a [11-20] direction. Thereafter a GaN layer 170 is grown on the principal surface of the GaAs substrate 150 in the [0001] direction by HVPE (hydride vapor phase epitaxy).

Thus, when the GaN layer 170 is grown, dislocations are formed on the seeds for generating the dislocation 160 and the GaN layer 170 having a saw blade shaped irregular section in which regions on the seeds for generating the dislocation 160 are valleys, as shown in FIG. 2. Irregular inclined surfaces of the GaN layer 170 (facets 170a) are (11-22) planes. Then, when the growth proceeds in the [0001] direction while maintaining this sectional shape, dislocations existing on the facets 170a moves to valleys 170b. Thus, the dislocation concentrated regions 12 are formed on the seeds for generating the dislocation 160 parallel to the (11-20) plane at intervals of about 200 μm in the [11-20] direction. When the GaN layer 170 is grown, an impurity is not relatively incorporated into mountain portions 170c of the irregular shape located on substantially centers of the adjacent dislocation concentrated regions 12. Thus, the high resistance regions 13 including a relatively small amount of impurities are formed on the substantially intermediate portions between the adjacent dislocation concentrated regions 12. Thus, the GaN layer 170 having the dislocation concentrated region 12 and the high resistance region 13 is formed.

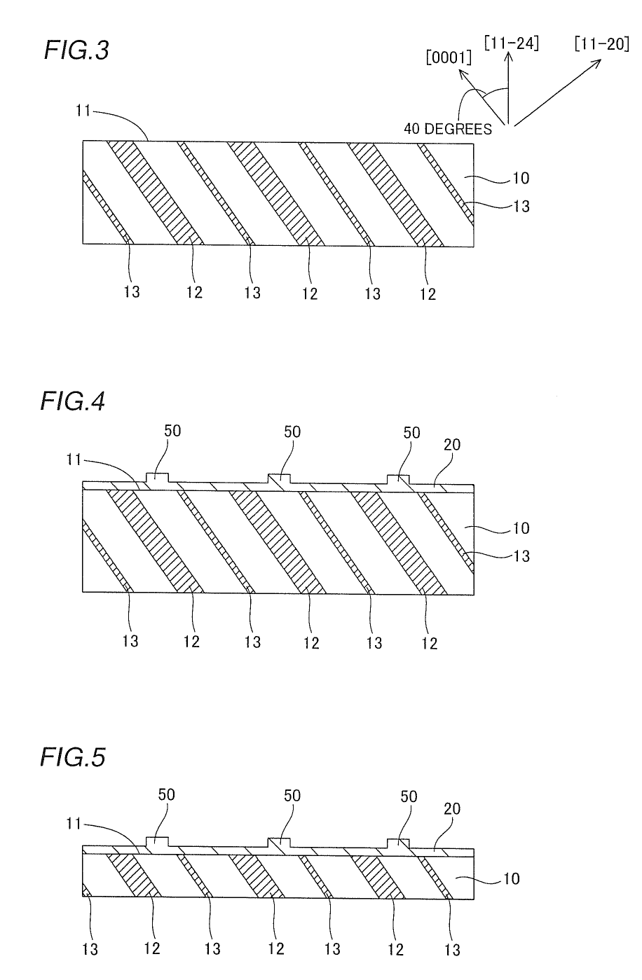

Thereafter the GaAs substrate 150 is removed, and the GaN layer 170 is sliced along a slice plane 180 parallel to the (11-24) plane inclined from a (0001) plane in the [11-20] direction by about 40 degrees. Thus, the substrate 10 made of GaN, in which the principal surface 11 is substantially equal to the (11-24) plane and the dislocation concentrated regions 12 are so arranged as to obliquely extend with respect to the principal surface 11, is formed, as shown in FIG. 3. The dislocation concentrated regions 12 are arranged in the principal surface 11 of the substrate 10 at intervals of about 312 μm. The high resistance regions 13 are arranged on the centers between the adjacent dislocation concentrated regions 12. The substrate 10 has a thickness of about 350 μm in this state.

As shown in FIG. 4, the semiconductor layer 20 comprising the buffer layer 21 (see FIG. 1), the n-side cladding layer 22, the n-side carrier blocking layer 23, the emission layer 24, the p-side optical guide layer 25, the p-side carrier blocking layer 26, the p-side cladding layer 27 and the p-side contact layer 28 is formed on the substrate 10 by MOCVD.

More specifically, the substrate 10 is inserted into a reactor of a hydrogen-nitrogen atmosphere, and the substrate 10 is heated up to a temperature of about 1000° C. in the state of supplying NH₃ gas employed as a nitrogen source for the semiconductor layer 20. When the substrate 10 reaches the temperature of about 1000° C., hydrogen gas containing TMGa (trimethylgallium) gas and TMAl (trimethylaluminum) gas employed as Ga and Al sources respectively are supplied into the reactor, thereby growing the buffer layer 21 (see FIG. 1) made of Al_{0.01}Ga_{0.99}N with a thickness of about 1.0 μm on the substrate 10.

Then, hydrogen gas containing TMGa (trimethylgallium) gas and TMAl (trimethylaluminum) gas employed as Ga and Al sources respectively and GeH₄ gas (monogerman) employed as a Ge source for obtaining an n-type conductivity are supplied into the reactor, thereby growing the n-side cladding layer 22 (see FIG. 1) made of Al_{0.07}Ga_{0.93}N having a thickness of about 1.9 μm. Thereafter hydrogen gas containing TMGa and TMAl is supplied into the reactor, thereby growing the n-side carrier blocking layer 23 (see FIG. 1) of Al_{0.2}Ga_{0.8}N with a thickness of about 20 nm.

The temperature of the substrate 10 is reduced to about 850° C. and TEGa (Triethylgallium) gas and TMIn (trimethylindium) gas employed as Ga and In sources respectively are supplied in a nitrogen atmosphere supplied with NH₃ while changing the flow rates thereof. Thus, the emission layer 24 (see FIG. 1) made of an MQW active layer having a multiple quantum well structure obtained by alternately stacking the three quantum well layers made of InₓGa₁₋ₓN and the three quantum barrier layers made of In_{y}Ga_{1-y}N is formed. Thereafter TMGa and TMAl are supplied into the reactor, thereby successively growing the p-side optical guide layer 25 made of In_{0.01}Ga_{0.99}N having a thickness of about 80 nm and the p-side carrier blocking layer 26 (see FIG. 1) made of Al_{0.25}Ga_{0.75}N having a thickness of about 20 nm on the upper surface of the emission layer 24.

In a hydrogen-nitrogen atmosphere supplied with NH₃ gas, the temperature of the substrate is heated up to a temperature of about 1000° C. and Mg(C₅H₅)₂ (cyclopentadienyl magnesium) employed as an Mg source serving as a p-type impurity and TMGa (trimethylgallium) gas and TMAl (trimethylaluminum) gas employed as Ga and Al sources respectively are supplied into the reactor, thereby growing the p-type cladding layer 27 (see FIG. 1) made of Al_{0.07}Ga_{0.93}N with a thickness of about 0.45 μm. Then the temperature of the substrate is reduced to about 850° C. and TEGa (Triethylgallium) gas and TMIn (trimethylindium) gas employed as Ga and In sources respectively are supplied in a nitrogen atmosphere supplied with NH₃, thereby forming the p-side contact layer 28 (see FIG. 1) made of In_{0.07}Ga_{0.93}N. The semiconductor layer 20 is grown on the substrate 10 made of GaN by MOCVD in the aforementioned manner.

Thereafter the temperature of the substrate is reduced to the room temperature and the substrate 10 stacked with the semiconductor layer 20 is taken out from the reactor.

As shown in FIG. 4, SiO₂ is employed as a mask for partially patterning the p-side contact layer 28 and the p-side cladding layer 27 by RIE (reactive ion etching) employing Cl₂ gas, thereby forming the ridge portions 50 for forming the waveguides. At this time, the ridge portions 50 are formed on positions separated from the dislocation concentrated regions 12 existing on the principal surface 11 of the substrate 10 along the principal surface 11 by about 83 μm. In this etching, the p-side contact layer 28 is patterned and the p-side cladding layer 27 is etched for remaining a thickness of about 0.05 μm in each p-side cladding layer 27 (see FIG. 1) having a thickness of about 0.45 μm, thereby forming the projecting portions 27a of the p-side cladding layer 27. Thus, the ridge portions 50 containing the projecting portions 27a of the p-side cladding layer 27 and the p-side contact layers 28 are formed. The ridge portions 50 are formed parallel to each other so as to extend in the [1-100] direction (perpendicular to the plane of FIG. 1).

Thereafter the p-side ohmic electrodes 29 are formed on the p-side contact layers 28 located on upper surfaces of the ridge portions 50. The current blocking layers 30 (see FIG. 1) made of SiO₂ are so formed as to cover the upper surfaces of the p-side cladding layer 27 and the side surfaces of the ridge portions 50 and the p-side ohmic electrodes 29. Thereafter the p-side pad electrode 31 (see FIG. 1) is formed to cover the upper surfaces of the p-side ohmic electrodes 29 and the current blocking layers 30. Thereafter the n-side ohmic electrodes 41 and the n-side pad electrodes 42 (see FIG. 1) are successively formed on the back surface of the substrate 10 after polishing the back surface of the substrate 10 up to a thickness allowing easy cleavage (about 100 μm), as shown in FIG. 5.

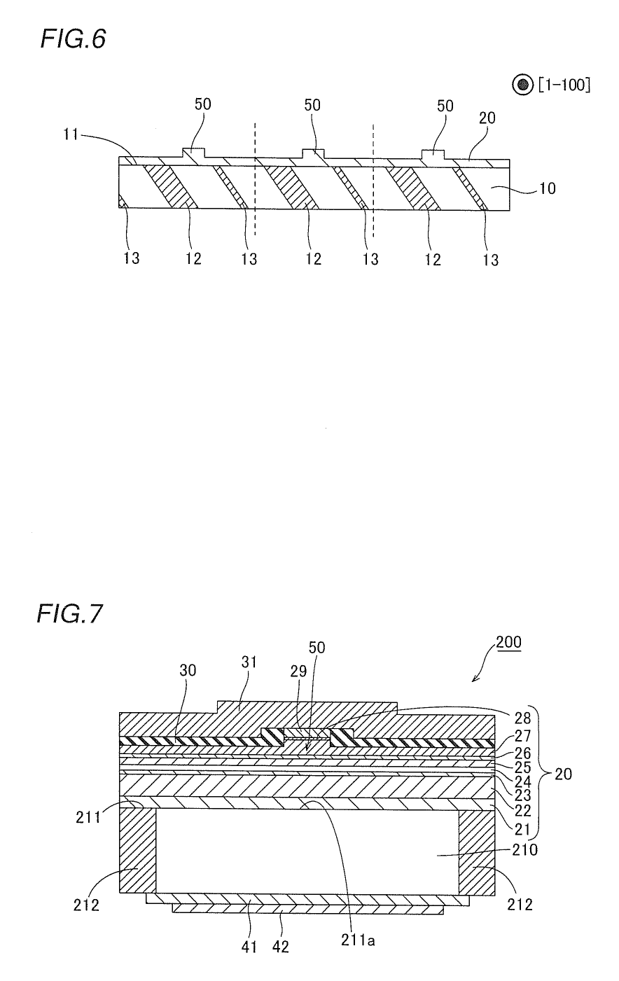

Although not shown, cleavage is performed parallel to a (1-100) plane for forming cavity facets and facet coating films (not shown) are formed on both facets (both cavity facets). Thereafter singulation process is performed by dividing the devices along a [1-100] direction on positions of the both sides of the ridge portions, separated in a direction perpendicular to the extensional direction of each ridge portion 50 (perpendicular to the plane of FIG. 1) by about 156 μm, as shown in FIG. 6. According to the first embodiment, the semiconductor laser device 100 is manufactured in the aforementioned manner.

A comparative experiment demonstrating effects of the present invention will be now described with reference to FIGS. 1, 2 and 7 to 9.

In this comparative experiment, vertical transverse modes of the semiconductor laser device 100 according to the first embodiment shown in FIG. 1 and a semiconductor laser device 200 according to a comparative example shown in FIG. 7 were measured in order to demonstrate the effects of the semiconductor laser device 100 according to the first embodiment. The semiconductor laser device 200 according to the comparative example was prepared in the following manner.

A GaAs substrate 150 (see FIG. 2) was removed from a GaN layer 170 similar to the aforementioned first embodiment and the GaN layer 170 was sliced along a plane parallel to a (0001) plane. Thus, a substrate 210, in which a principal surface 211 was substantially equal to a (0001) plane and dislocation concentrated regions 212 were so arranged as to extend in a direction perpendicular to the principal surface 211, was formed as shown in FIG. 7. Then a semiconductor layer 20, a p-side ohmic electrode 29, current blocking layers 30, a p-side pad electrode 31, an n-side ohmic electrode 41 and an n-side pad electrode 42 were formed employing the substrate 210 through a process similar to that of the aforementioned first embodiment.

In the semiconductor laser device 200 according to the comparative example, the dislocation concentrated regions 212 are arranged on both end of the substrate 210. A ridge portion 50 is formed on a region 211a except regions where the dislocation concentrated regions 212 are present in the principal surface 211 of the substrate 210.

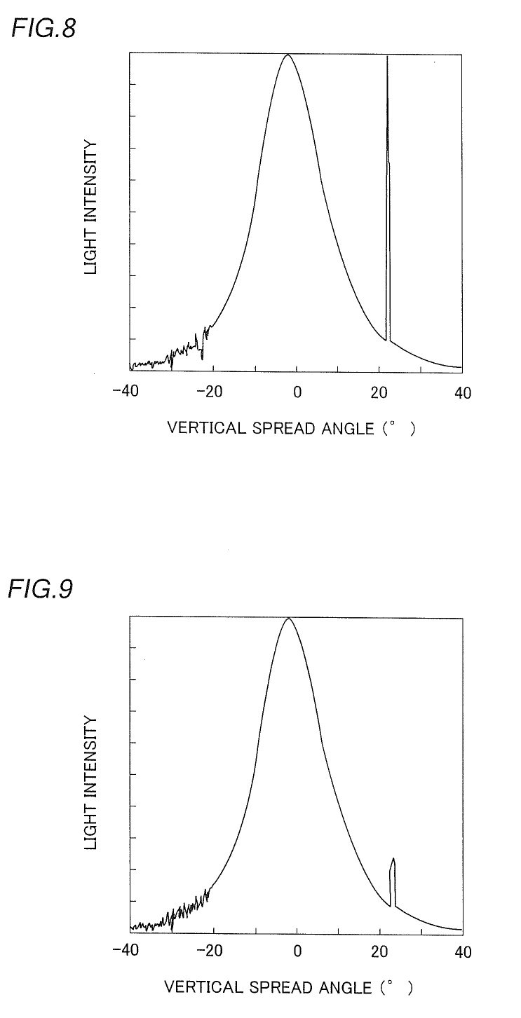

In the vertical transverse mode of the semiconductor laser device 200 according to the comparative example prepared in the aforementioned manner, a strong peak is present in the vicinity of 20 degrees, as shown in FIG. 8. This strong peak is conceivably for the following reason: The substrate 210 made of GaN has a refractive index larger than that of the n-side cladding layer 22 made of AlGaN and hence light easily leaks from the n-side cladding layer 22 to the substrate 210. The light leaking to the substrate 210, mixed with a laser, emits and hence a peak corresponding to the light emitting from the substrate 210 is conceivably present in the vertical transverse mode shown in FIG. 8.

As shown in FIG. 9, in the vertical transverse mode of the semiconductor laser device 100 according to the first embodiment, a weak peak is present in the vicinity of 20 degrees. This weak peak is conceivably for the following reason: Also in the semiconductor laser device 100 according to the first embodiment, the substrate 10 made of GaN has a refractive index larger than that of the n-side cladding layer 22 made of AlGaN and hence light easily leaks from the n-side cladding layer 22. As shown in FIG. 1, the dislocation concentrated region 12 is arranged below the ridge portion 50 in the substrate 10 of the semiconductor laser device 100 according to the first embodiment. This dislocation concentrated region 12 has a function of absorbing light and hence light leaking from the n-side cladding layer 22 to the substrate 10 is conceivably absorbed in the dislocation concentrated region 12. Therefore, intensity of light emitting from the substrate 10 is reduced since the light is absorbed in the dislocation concentrated region 12, and hence the peak in the vicinity of 20 degrees is conceivably reduced as shown in FIG. 9.

According to the first embodiment, as hereinabove described, the ridge portion 50 is located above the dislocation concentrated region 12 and also located on the region except the portion where the dislocation concentrated region 12 is present in the principal surface 11 of the substrate 10, whereby the dislocation concentrated region 12 can absorb the light leaking from the ridge portion 50 to a side of the substrate 10. Thus, the strong peak can be inhibited from appearing on the side of the substrate of the vertical transverse mode. Consequently, the vertical transverse mode can be inhibited from being brought into a higher mode and hence an excellent vertical transverse mode can be obtained.

According to the first embodiment, the dislocation concentrated region 12 is so formed in the substrate 10 as to obliquely extend with respect to the principal surface 11 of the substrate 10 and the ridge portion 50 is so formed as to be located on the region except the portion where the dislocation concentrated region 12 is present in the principal surface 11 of the substrate 10, whereby a current path without passing through the dislocation concentrated region 12 having a high resistance can be provided in the substrate 10. Thus, a current can flow while avoiding the dislocation concentrated region 12 having the high resistance and hence increase in the resistance of the current path can be suppressed.

According to the first embodiment, the ridge portion 50 is provided on the region 11a except the portions where the dislocation concentrated region 12 and the high resistance region 13 are present in the principal surface 11 of the substrate 10, whereby a current can flow while avoiding not only the dislocation concentrated region 12 but also the high resistance region 13 when driving the semiconductor laser device 100, and hence increase in the resistance of the current path can be suppressed.

According to the first embodiment, the dislocation concentrated region 12 is so arranged as to obliquely extend inside the substrate 10 and reach the region below the ridge portion 50, whereby the dislocation concentrated region 12 can reliably absorb light leaking from the n-side cladding layer 22 on the lower portion of the ridge portion 50 to the side of the substrate 10.

According to the first embodiment, the dislocation concentrated region 12 and the high resistance region 13 are so arranged as to extend along the extensional direction of the ridge portion 50 ([1-100] direction), whereby the region (current path), where a current flows while avoiding the dislocation concentrated region 12 and the high resistance region 13, is formed along the extensional direction of the ridge portion 50, and hence increase in the resistance of the current path also along the cavity direction of the semiconductor laser device 100 can be suppressed.

According to the first embodiment, the dislocation concentrated region 12 is so arranged as to extend from the principal surface 11 of the substrate 10 up to the lower surface of the substrate 10, whereby the substrate 10 has the region completely blocked from the principal surface 11 to the lower surface of the substrate 10 along the thickness direction of the substrate 10 by the dislocation concentrated region 12 and hence the dislocation concentrated region 12 can reliably absorb the light leaking from the ridge portion 50 to the side of the substrate 10 below the ridge portion 50.

According to the first embodiment, the high resistance region 13 is so arranged as to extend from the principal surface 11 of the substrate 10 up to the lower surface of the substrate 10, whereby a current can easily flow from the principal surface 11 (region 11a) of the substrate 10 toward the lower surface while avoiding not only the aforementioned dislocation concentrated region 12 but also the high resistance region 13 when driving the semiconductor laser device 100.

According to the first embodiment, the dislocation concentrated region 12 and the high resistance region 13 are so arranged in the substrate 10 as to extend substantially parallel to each other at the prescribed interval (about 156 μm), whereby the sectional area of the current path can be formed substantially constant along the extensional direction of the ridge portion 50 ([1-100] direction) and hence the resistance value of the current path along the cavity direction of the semiconductor laser device 100 can be inhibited from dispersion.

According to the first embodiment, the ridge portion 50 is so formed as to be located on the region 11a held between the portion where the dislocation concentrated region 12 is present and the portion where the high resistance region 13 is present in the principal surface 11 of the substrate 10, whereby the waveguide formed on the lower portion of the ridge portion 50 can be reliably arranged on the region 11a.

According to the first embodiment, the width (about 156 μm) of the region 11a held between the portion where the dislocation concentrated region 12 is present and the portion where the high resistance region 13 is present is formed to be larger than the width (about 1.5 μm) of the ridge portion 50, whereby the waveguide formed on the lower portion of the ridge portion 50 can be reliably arranged only on the region 11a.

According to the first embodiment, the n-type ohmic electrode 41 is so formed as to cover the dislocation concentrated region 12, the high resistance region 13 and the region held between the portion where the dislocation concentrated region 12 is present and the portion where the high resistance region 13 is present in the lower surface of the substrate 10, whereby a current flowing in the region 11a serving as the current path can be reliably collected by the n-type ohmic electrode 41 on the lower surface of the substrate 10. According to the aforementioned structure, the n-type ohmic electrode 41 can inhibit the light leaking from the n-side cladding layer 22 to the substrate 10 from emitting from the lower surface of the substrate 10 to the outside.

According to the first embodiment, the principal surface 11 of the substrate 10 is substantially equal to the (11-24) plane or a plane equivalent to this plane, whereby the semiconductor layer 20 can be formed on a semipolar plane ((11-24) plane or the plane equivalent to this plane) inclined by about 40 degrees with respect to the (0001) plane when forming the semiconductor layer 20 on the substrate 10. In the semiconductor laser device 100 employing the substrate 10 having the plane inclined by about 40 degrees with respect to the (0001) plane as the principal surface 11, a piezoelectric field can be suppressed and hence high luminous efficiency can be obtained.

According to the first embodiment, the semiconductor layer 20 is formed by the nitride-based semiconductor made of AlGaN or InGaN, whereby it is possible to produce the blue-violet semiconductor laser capable of suppressing increase in the resistance of the current path and obtaining an excellent vertical transverse mode.

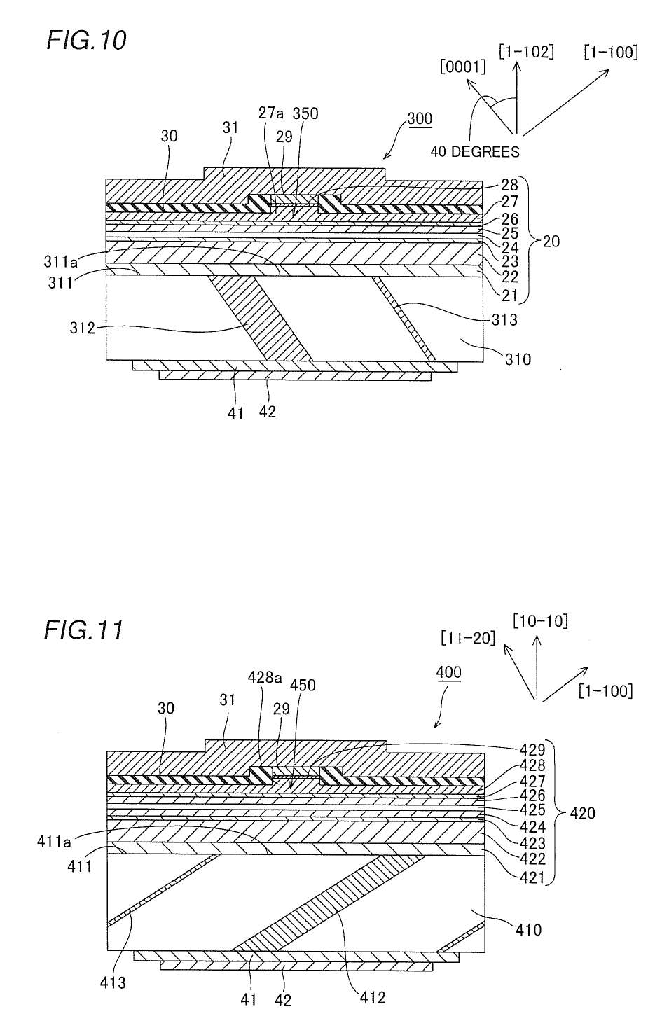

While the substrate 10 obtained by slicing the GaN layer 170 formed with the dislocation concentrated region 12 parallel to the (11-20) plane, along the (11-24) plane inclined from the (0001) plane in the [11-20] direction by about 40 degrees is employed, and the ridge portion 50 is formed parallel to the [1-100] direction, so that the (1-100) plane serves as the cavity facets, in the aforementioned first embodiment, the present invention is not restricted to this. In other words, a substrate 310 obtained by slicing a GaN layer (not shown) formed with a dislocation concentrated region parallel to a (1-100) plane, along a (1-102) plane inclined from a (0001) plane in a [1-100] direction by about 40 degrees may be employed as in a semiconductor laser device 300 of a modification shown in FIG. 10 and a ridge portion 350 may be formed parallel to a [11-20] direction, so that a (11-20) plane serves as cavity facets. Also in the semiconductor laser device 300, a dislocation concentrated region 312 and a high resistance region 313 are so arranged as to obliquely extend with respect to a principal surface 311 of the substrate 310. The ridge portion 50 is provided on a region 311a except portions, where the dislocation concentrated region 312 and the high resistance region 313 are present, in the principal surface 311 of the substrate 310. Also in this structure, the semiconductor laser device employing the substrate 310 having a plane inclined by about 40 degrees with respect to the (0001) plane as the principal surface 311 is obtained and hence a piezoelectric field can be suppressed. The remaining effects of the modification are similar to those of the aforementioned first embodiment.

### Second Embodiment

Referring to FIG. 11, a substrate is sliced along a (10-10) plane in a second embodiment dissimilar to the aforementioned first embodiment in which the substrate is sliced along the plan inclined from the (0001) plane to the [11-10] direction by about 40 degrees. In this second embodiment, the present invention is applied to a green semiconductor laser dissimilarly to the aforementioned first embodiment in which the present invention is applied to the blue-violet semiconductor laser.

As shown in FIG. 11, a semiconductor laser device 400 according to the second embodiment comprises a substrate 410, a semiconductor layer 420, a p-side ohmic electrode 29, current blocking layers 30, a p-side pad electrode 31, an n-side ohmic electrode 41 and an n-side pad electrode 42.

The substrate 410 is made of n-type GaN and has a thickness of about 100 μm. According to the second embodiment, a principal surface 411 of the substrate 410 is substantially equal to the (10-10) plane. In the substrate 410, a dislocation concentrated region 412 and high resistance regions 413 are so arranged as to extend along a (11-20) plane. The dislocation concentrated region 412 and the high resistance regions 413 are inclined by about 30 degrees with respect to the principal surface 411 of the substrate 410.

The semiconductor layer 420 according to the second embodiment has a composition different from that of the semiconductor layer 20 according to the aforementioned first embodiment and provided with an n-side optical guide layer 424. More specifically, the semiconductor layer 420 includes a buffer layer 421 made of Al_{0.01}Ga_{0.99}N, formed on the substrate 410, an n-side cladding layer 422 made of n-side Al_{0.03}Ga_{0.97}N doped with Ge, formed on the buffer layer 421, an n-side carrier blocking layer 423 made of Al_{0.1}Ga_{0.09}N, formed on the n-side cladding layer 422, an n-side optical guide layer 424 made of In_{0.05}Ga_{0.95}N, formed on the n-side carrier blocking layer 423 and an emission layer 425 formed on the n-side optical guide layer 424. The semiconductor layer 420 further includes a p-side optical guide layer 426 made of In_{0.05}Ga_{0.95}N, formed on the emission layer 425, a p-side carrier blocking layer 427 made of Al_{0.1}Ga_{0.9}N, formed on the p-side optical guide layer 426, a p-side cladding layer 428 made of Al_{0.03}Ga_{0.97}N, formed on the p-side carrier blocking layer 427 and a p-side contact layer 429 made of In_{0.07}Ga_{0.93}N, formed on the p-side cladding layer 428. The emission layer 425 is made of an MQW active layer obtained by alternately stacking two quantum well layers made of InₓGa₁₋ₓt, each having a thickness of about 2.5 nm and three quantum barrier layers made of In_{y}Ga_{1-y}N, each having a thickness of about 20 nm. In this embodiment, x>y, and x=0.55 and y=0.25. According to this structure, the semiconductor layer 420 emits a green laser.

The p-side cladding layer 428 is provided with a projecting portion 428a having a thickness of about 0.4 μm. The p-side contact layer 429 is formed on the projecting portion 428a of the p-side cladding layer 428. The projecting portion 428a of the p-side cladding layer 428 and the p-side contact layer 429 form a ridge portion 450 for forming a waveguide. The ridge portion 450 is so formed as to extend in a [0001] direction (perpendicular to the plane of FIG. 11). The ridge portion 450 is formed on a region 411a except portions where the dislocation concentrated region 412 and the high resistance region 413 are present in the principal surface 411 of the substrate 410. The remaining structure of the semiconductor laser device 400 according to the second embodiment is similar to that of the aforementioned first embodiment.

A fabricating process for the semiconductor laser device 400 according to the second embodiment will be now described with reference to FIGS. 2 and 11 to 16.

As a fabricating process for the substrate 410, the GaN layer 170 (see FIG. 2) having the dislocation concentrated region 12 and the high resistance region 13 is formed similarly to the aforementioned first embodiment.

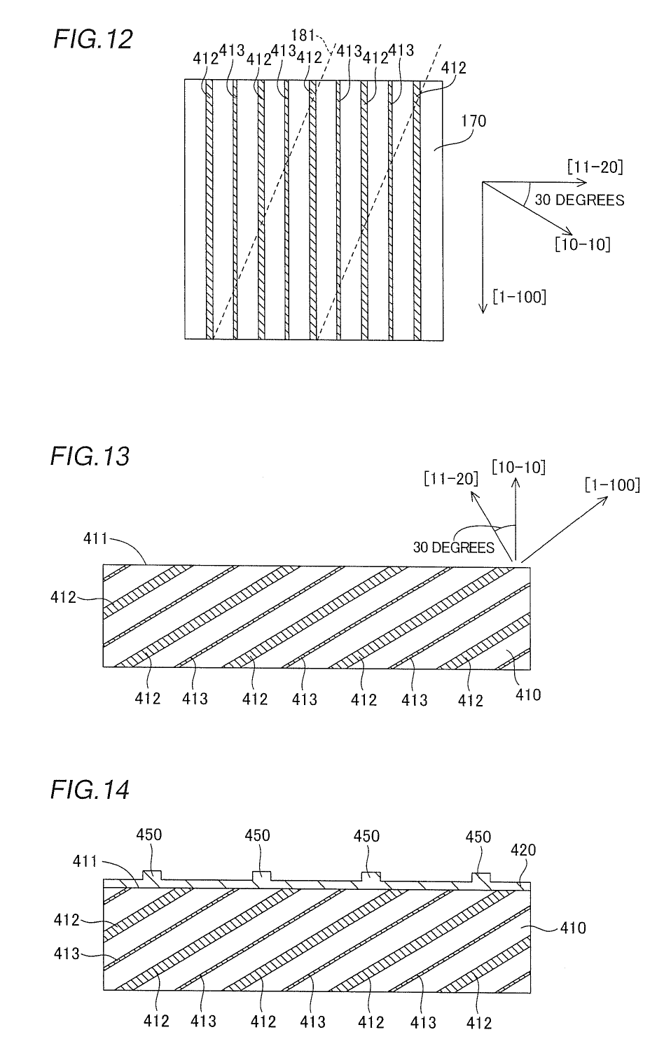

Thereafter the GaAs substrate 150 (see FIG. 2) is removed and the GaN layer 170 is sliced along a plane 180 parallel to the (10-10) plane inclined from the (11-20) plane in a [1-100] direction by about 30 degrees, as shown in FIG. 12. Thus, the substrate 410, in which the principal surface 411 is substantially equal to the (10-10) plane and the dislocation concentrated regions 412 and the high resistance regions 413 are so arranged as to obliquely extend with respect to the principal surface 411, is formed, as shown in FIG. 13. The dislocation concentrated regions 412 are arranged in the principal surface 411 of the substrate 410 at intervals of about 400 μm. The high resistance regions 413 are arranged on the centers between the adjacent dislocation concentrated regions 412. The substrate 410 has a thickness of about 350 μm in this state.

The semiconductor layer 420 (see FIG. 14) is formed on the substrate 410 by MOCVD through a fabricating process similar to the aforementioned first embodiment.

Thereafter the temperature of the substrate is reduced to the room temperature and the substrate 410 stacked with the semiconductor layer 420 formed by the buffer layer 421, the n-side cladding layer 422, the n-side carrier blocking layer 423, the n-side optical guide layer 424, the emission layer 425, the p-side optical guide layer 426, the p-side carrier blocking layer 427, the p-side cladding layer 428 and the p-side contact layer 429 is taken out from a reactor.

As shown in FIG. 14, SiO₂ is employed as a mask for partially patterning the p-side contact layer 429 and the p-side cladding layer 428 by RIE (reactive ion etching) employing Cl₂ gas, thereby forming the ridge portions 450 for forming the waveguides containing the projecting portion 428a of the p-side cladding layer 428 and the p-side contact layer 429. The ridge portions 450 are formed parallel to each other so as to extend in the [0001] direction (perpendicular to the plane of FIG. 11).

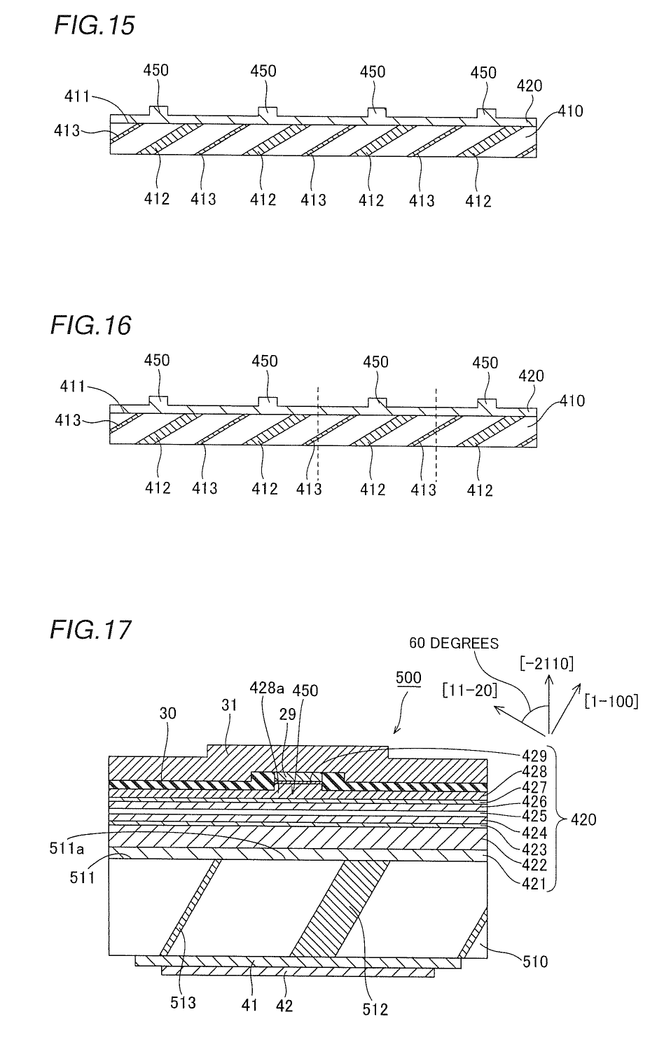

The p-side ohmic electrode 29, the current blocking layers 30 and the p-side pad electrode 31 are formed similarly to the aforementioned first embodiment. Thereafter the n-side ohmic electrodes 41 and the n-side pad electrodes 42 are successively formed on the back surface of the substrate 410 after polishing the back surface of the substrate 410 up to a thickness allowing easy cleavage (about 100 μm), as shown in FIG. 15.

Then, cleavage is performed parallel to the (0001) plane for forming cavity facets and facet coating films (not shown) are formed on both facets (both cavity facets) Thereafter singulation process is performed by dividing the devices on positions of the both sides of the ridge portions 450, separated in a direction perpendicular to the extensional direction of each ridge portion 450 (perpendicular to the plane of FIG. 1) by about 200 μm, as shown in FIG. 16. According to the second embodiment, the semiconductor laser device 400 is manufactured in the aforementioned manner.

According to the second embodiment, as hereinabove described, the ridge portion 450 is located above the dislocation concentrated region 412 and also located on the region except the portion where the dislocation concentrated region 412 is present in the principal surface 411 of the substrate 410, whereby the dislocation concentrated region 412 can absorb the light leaking from the ridge portion 450 to a side of the substrate 410. Thus, the strong peak can be inhibited from appearing on the side of the substrate of the vertical transverse mode. Consequently, the vertical transverse mode can be inhibited from being brought into a higher mode and hence an excellent vertical transverse mode can be obtained.

According to the second embodiment, the principal surface 411 of the substrate 410 is substantially equal to the (10-10) plane, whereby the semiconductor layer 420 can be formed on the (10-10) plane employed as a nonpolar plane inclined by about 90 degrees with respect to the (0001) plane when forming the semiconductor layer 420 on the substrate 410. In the semiconductor laser device 400 employing the substrate 410 having the nonpolar plane as the principal surface 411, a piezoelectric field can be suppressed.

According to the second embodiment, the principal surface 411 of the substrate 410 is substantially equal to the (10-10) plane, whereby the dislocation concentrated region 412 can be arranged so as to obliquely extend with respect to the principal surface 411 parallel to the (10-10) plane when the dislocation concentrated region 412 is formed on the (11-20) plane. The remaining effects of the second embodiment are similar to those of the aforementioned first embodiment.

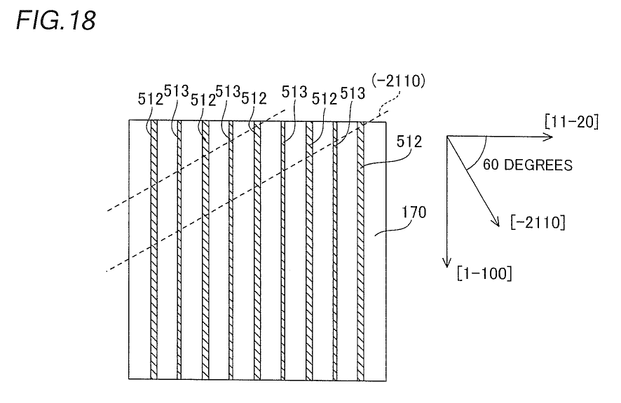

While the GaN layer 170 is sliced along the (10-10) plane inclined from the (11-20) plane in the [1-100] direction by 30 degrees in the aforementioned second embodiment, the present invention is not restricted to this but the GaN layer 170 may be sliced along a (−2110) plane inclined from the (11-20) plane in the [1-100] direction by 60 degrees as in a semiconductor laser device 500 of a modification shown in FIGS. 17 and 18. A substrate 510 of the semiconductor laser device 500 has a principal surface 511 parallel to the (−2110) plane and has a dislocation concentrated region 512 and high resistance regions 513 along the (11-20) plane inclined by 60 degrees with respect to the principal surface 511. A ridge portion 450 is provided on a region 511a except portions where the dislocation concentrated region 512 and the high resistance region 513 are present in the principal surface 511 of the substrate 510.

Although the present invention has been described and illustrated in detail, it is clearly understood that the same is by way of illustration and example only and is not to be taken by way of limitation, the spirit and scope of the present invention being limited only by the terms of the appended claims.

For example, while the aforementioned embodiments of the present invention are applied to the blue-violet and green semiconductor laser devices, the present invention is not restricted to this but is also applicable to a violet or blue semiconductor laser device.

While the aforementioned embodiments of the present invention are applied to the nitride-based semiconductor made of AlGaN, the present invention is not restricted to this but is also applicable to a nitride-based semiconductor made of BN, GaN, AlN, InN, TlN or alloyed semiconductors thereof.

While the ridge portion for forming the waveguide is provided in each of the aforementioned embodiments, the present invention is not restricted to this but a buried-type, mesa-type or slab-type waveguide may be alternatively provided.

What is claimed is:

1. A semiconductor laser device comprising:
a substrate made of a nitride-based semiconductor; and
a waveguide formed on a principal surface of said substrate, wherein
said substrate includes a dislocation concentrated region arranged so as to obliquely extend with respect to said principal surface of said substrate, and
said waveguide is so formed as to be located above said dislocation concentrated region and also located on a region except a portion where said dislocation concentrated region is present in said principal surface of said substrate.

2. The semiconductor laser device according to claim 1, wherein
said substrate further includes a high resistance region, and
said waveguide is so formed as to be located on a region except portions where said dislocation concentrated region and said high resistance region are present in said principal surface of said substrate.

3. The semiconductor laser device according to claim 1, wherein
said dislocation concentrated region is so arranged as to obliquely extend inside said substrate to reach a lower region of said waveguide.

4. The semiconductor laser device according to claim 1, wherein
said dislocation concentrated region is so arranged as to extend along an extensional direction of said waveguide.

5. The semiconductor laser device according to claim 1, wherein
said dislocation concentrated region is so arranged as to extend from said principal surface of said substrate up to a lower surface of said substrate opposite to said principal surface.

6. The semiconductor laser device according to claim 1, wherein
said waveguide extends along a [1-100] direction.

7. The semiconductor laser device according to claim 1, wherein
said waveguide extends along a [11-20] direction.

8. The semiconductor laser device according to claim 2, wherein
said high resistance region is so arranged as to extend along an extensional direction of said waveguide.

9. The semiconductor laser device according to claim 2, wherein
said high resistance region is so arranged as to extend from said principal surface of said substrate up to a lower surface of said substrate opposite to said principal surface.

10. The semiconductor laser device according to claim 2, wherein
said dislocation concentrated region and said high resistance region are so arranged inside said substrate as to extend substantially parallel to each other at a prescribed interval.

11. The semiconductor laser device according to claim 2, wherein
said waveguide is so formed as to be located on a region held between said portion where said dislocation concentrated region is present and said portion where said high resistance region is present in said principal surface of said substrate.

12. The semiconductor laser device according to claim 2, further comprising a ridge portion formed on said principal surface of said substrate, wherein
said waveguide is formed on a lower portion of said ridge portion.

13. The semiconductor laser device according to claim 12, wherein
a width of said region held between said portion where said dislocation concentrated region is present and said portion where said high resistance region is present in said principal surface of said substrate is larger than that of said waveguide.

14. The semiconductor laser device according to claim 2, further comprising an electrode layer formed on a lower surface of said substrate opposite to said principal surface, wherein
said electrode layer is so formed as to cover at least a region held between a portion where said dislocation concentrated region is present and a portion where said high resistance region is present in said lower surface.

15. The semiconductor laser device according to claim 1, wherein
said principal surface of said substrate is a semipolar plane.

16. The semiconductor laser device according to claim 1, wherein
said principal surface of said substrate is substantially equal to a (1-102) plane, a (11-24) plane or a plane equivalent to these planes.

17. The semiconductor laser device according to claim 1, wherein
said principal surface of said substrate is substantially equal to a (lmn0) plane (l, m and n are integers).

18. The semiconductor laser device according to claim 17, wherein
said principal surface of said substrate is substantially equal to a (10-10) plane, a (−2110) plane or a plane equivalent to these planes.

19. The semiconductor laser device according to claim 1, further comprising a semiconductor layer made of a nitride-based semiconductor, formed on said substrate.
